(19) United States
(12) Patent Application Publication
(10) Pub. No.: US 2013/0271974 A1
(43) Pub. Date: Oct. 17, 2013

(54) LIGHT-EMITTING DIODE MODULE WITH A FIRST COMPONENT AND A SECOND COMPONENT AND METHOD FOR THE PRODUCTION THEREOF

(71) Applicants: Gerhard Kuhn, Kofering (DE); Ales Markytan, Regensburg (DE); Christian Gärtner, Neutraubling (DE)

(72) Inventors: Gerhard Kuhn, Kofering (DE); Ales Markytan, Regensburg (DE); Christian Gärtner, Neutraubling (DE)

(73) Assignee: OSRAM Opto Semiconductors GmbH, Regensburg (DE)

(21) Appl. No.: 13/878,257

(22) PCT Filed: Sep. 6, 2011
(86) PCT No.: PCT/EP2011/065400

§ 371 Date: Jun. 27, 2013

(30) Foreign Application Priority Data
Oct. 8, 2010 (DE) 10 2010 047 941.1

(51) Int. Cl. F21K 99/00; H01L 33/08

(52) U.S. Cl. CPC F21K 9/00; H01L 33/08
USPC 362/231; 438/22

(57) ABSTRACT

A light-emitting diode module has a first component and a second component, wherein the module exhibits a first operating mode and a second operating mode. The first component exhibits a first luminous flux. The second component exhibits a second luminous flux. In the first operating mode, the ratio of the first and second luminous fluxes is set such that the module emits mixed radiation with a color rendering index of 80 to 97. In the second operating mode, the ratio of the first and second luminous fluxes is set such that the module emits mixed radiation with a color rendering index of 55 to 70.

### TECHNICAL FIELD

This disclosure relates to a light-emitting diode module with a first radiation-emitting component and a second radiation-emitting component as well as a method of producing such a light-emitting diode module.

### BACKGROUND

DE 10 2005 037 571 A1 describes a system that controls lighting.

Lighting modules used, for example, as street lighting conventionally comprise a plurality of LEDs operated in an operating mode in which a desired radiation emission and a desired color location for the radiation emitted by the module are generated. Care is taken to ensure that the module has the highest possible color rendering index in this operating mode.

In a module which comprises a plurality of LEDs that emit radiation of differing wavelength and, consequently, have a differing light yield, achieving the highest possible color rendering index entails supplying the LEDs with elevated electrical power. If it is necessary or desired to reduce the electrical power of the module, the brightness of the LEDs is conventionally dimmed, or the “duty cycle,” i.e., the proportion of operating time, or operating current reduced. Conventionally, however, the various LEDs are all dimmed to an identical extent in such a case.

It could therefore be helpful to provide a light-emitting diode module distinguished by reduced power input to the module and at the same time by an elevated light yield from the module, and a method of producing such a light-emitting diode module.

### SUMMARY

We provide a light-emitting diode module including at least one first radiation-emitting component and one second radiation-emitting component and having a first operating mode and a second operating mode, wherein the first radiation-emitting component emits radiation of a first wavelength and exhibits a first luminous flux, the second radiation-emitting component emits radiation of a second wavelength different from the first wavelength and exhibits a second luminous flux, at least a ratio of the first luminous flux to the second luminous flux in the first operating mode is set such that the module emits mixed radiation with a color rendering index of 80 to 97, at least a ratio of the first luminous flux to the second luminous flux in the second operating mode is set such that the module emits mixed radiation with a color rendering index of 55 to 70, the first wavelength is in a red spectral range and the second wavelength is in a greenish-white spectral range, the lighting module is adapted for use in street lighting, tunnel lighting, indoor car park lighting and/or warehouse lighting, and the lighting module includes two operating modes.

We also provide a method of producing a light-emitting diode having at least one first radiation-emitting component and one second radiation-emitting component having a first operating mode and a second operating mode including providing a carrier, arranging the first radiation-emitting component and the second radiation-emitting component on the carrier, wherein the first radiation-emitting component emits radiation of a first wavelength and exhibits a first luminous flux, the second radiation-emitting component emits radiation of a second wavelength different from the first wavelength and exhibits a second luminous flux, at least a ratio of the first luminous flux to the second luminous flux in the first operating mode is set such that the module emits mixed radiation with a color rendering index of 80 to 97, at least a ratio of the first luminous flux to the second luminous flux in the second operating mode is set such that the module emits mixed radiation with a color rendering index of 55 to 70, the first wavelength is in a red spectral range and the second wavelength is in a greenish-white spectral range, the lighting module is adapted for street lighting, tunnel lighting, indoor car park lighting and/or warehouse lighting, and the lighting module includes two operating modes.

We further provide a light-emitting diode module including at least one first radiation-emitting component and one second radiation-emitting component and having a first operating mode and a second operating mode, wherein the first radiation-emitting component emits radiation of a first wavelength and exhibits a first luminous flux, the second radiation-emitting component emits radiation of a second wavelength different from the first wavelength and exhibits a second luminous flux, at least a ratio of the first luminous flux to the second luminous flux in the first operating mode is set such that the module emits mixed radiation with a color rendering index of 80 to 97, and at least a ratio of the first luminous flux to the second luminous flux in the second operating mode is set such that the module emits mixed radiation with a color rendering index of 55 to 70.

### BRIEF DESCRIPTION OF THE DRAWINGS

FIGS. 1A to 1C, 2A, 2B, 3A and 3B are each schematic cross-sections of an example of a light-emitting diode module in different operating modes.

FIG. 4 is a schematic flow chart relating to a production method.

FIG. 5 is a schematic view of the CIE standard chromaticity diagram, with values in our range being labelled.

### DETAILED DESCRIPTION

We provide a light-emitting diode module with at least one first radiation-emitting component and one second radiation-emitting component, the light-emitting diode module having a first operating mode and a second operating mode. The first radiation-emitting component emits radiation of a first wavelength and exhibits a first luminous flux. The second radiation-emitting component emits radiation of a second wavelength different from the first wavelength and exhibits a second luminous flux. In the first operating mode, at least the ratio of the first luminous flux to the second luminous flux is set such that the module emits mixed radiation with a color rendering index of 80 to 97. In the second operating mode, at least the ratio of the first luminous flux to the second luminous flux is set such that the module emits mixed radiation with a color rendering index of 55 to 70.

The term “color rendering index,” which is also abbreviated to CRI, is taken to mean a photometric variable used to describe the quality of the color rendering of radiation-emitting components of an identical, correlated color temperature. Color temperature is here a measure of the perceived color of a light source.

Luminous flux is a photometric variable which takes account of the wavelength-dependency of the sensitivity of the human eye, i.e., the V(λ) curve.

The light-emitting diode module thus has two operating modes set in accordance with the intended use of the module. If the intended use requires high quality for the radiation emitted by the light-emitting diode module, in particular a high color rendering index, the light-emitting diode module is set to the first operating mode. On the other hand, if a lower quality, i.e., a lower color rendering index is sufficient, the light-emitting diode module may be set to the second operating mode distinguished by reduced electrical power input to the module. According to the intended use and, as a function thereof, according to the set operating mode, the necessary electrical power input to the module may be optimized, in particular set in an economically appropriate manner. In particular, in the second operating mode the ratio of the first luminous flux to the second luminous flux may be set such that the necessary electrical power input to the module is reduced in the second mode in comparison with the first mode.

In particular, the light-emitting diode module comprises only the first and the second operating modes, i.e., in total precisely two operating modes. In other words, continuous adjustment between the operating modes, for example, is not possible. If the light-emitting diode module is operating properly, luminous flux is thus emitted according either to the first or to the second operating mode.

For example, in the second operating mode with a low color rendering index radiation-emitting components with a poor light yield are not necessarily connected for operation. Accordingly, at least in the second operating mode, a module is obtained which is distinguished by a reduced electrical power simultaneously combined with an elevated light yield. Modules may accordingly be obtained which exhibit a 20%-30% increase in efficiency.

The light yield is the quotient of the luminous flux output by the component and its absorbed electrical power.

In the second operating mode, just the second radiation-emitting component may be electrically drivable or driven. In this case, the first radiation-emitting component exhibits a lower light yield than the second such that the electrical power input to the module may be reduced on operation of just the second component. The luminous flux of the first component is here substantially zero.

Alternatively, both the first component and the second component may be electrically drivable or driven in the second operating mode. In this case, in the second operating mode the electrical power input to the first component and, hence, the luminous flux are reduced compared to the first operating mode, whereby a lower quality and a lower color rendering index are gener-ated while the electrical power input in the second operating mode is, however, advantageously reduced. If, in accordance with the intended use, a lower quality and a lower color rendering index are sufficient, operation of the same module in a reduced electrical mode is made possible.

The module thus has a reduced electrical mode and a high electrical mode and may be set to these modes depending on the desired application.

The module may be switchable between the first and the second operating mode. For instance, in accordance with the desired application, the module may, for example, be switched from the elevated electrical operating mode to the reduced electrical operating mode or vice versa.

The first radiation-emitting component and the second radiation-emitting component may be separately electrically drivable. As a function of the set operating mode, the first component and the second component may be electrically energized in an intended ratio to one another.

In the first operating mode and in the second operating mode the first and second components may additionally be dimmed. In this context, dimming means that operation of the first and/or second component continues with a lower current and/or operating voltage. In other words, the radiant intensity emitted by the components is reduced.

A drive circuit configured to drive or energize the first and/or second component electrically is known and therefore not described in greater detail at this point.

The first wavelength may be located in the red spectral range and the second wave-length in the greenish-white spectral range. Compared to greenish-white radiation-emitting components, red radiation-emitting components exhibit a lower light yield. In the second operating mode, the first luminous flux may in this case be set to a reduced level or deactivated. As a con-sequence, the electrical power supplied to the module is advantageously reduced. In the event of deactivation, the module emits radiation only from the second radiation-emitting component.

The wavelength of the mixed radiation in the first operating mode may be in the cool or warm white spectral range and the wavelength of the mixed radiation in the second operating mode may be in the greenish-white spectral range. The ratio of the luminous flux from the radiation-emitting components is thus configured in the first operating mode such that a fixed cool white or warm white color location is achieved.

The “color location” is in particular taken to mean the numerical values which describe the color of the emitted radiation in the CIE color space.

In the first operating mode, the module emits radiation with a color temperature of 2100 K to 6500 K close to the Planckian curve. A color rendering index in an elevated range of 80 to 97, preferably of 90, is achieved here.

In the second operating mode, the proportion of the luminous flux of the first component, in particular of the red emitting component, is reduced, or even set to zero such that the module emits the emitted radiation of the second component in the greenish-white spectral range. Since the second component advantageously exhibits a higher efficiency than the first component, in the second operating mode the electrical power input to the module may be set to a reduced level while achieving an identical luminous flux, thereby enabling a 20% to 30% increase in efficiency.

In the second operating mode the electrical power input to the first radiation-emitting component and/or the radiation emission thereof may be lower than the electrical power input to the second radiation-emitting component and/or the radiation emission thereof. Since the first component exhibits a lower light yield or radiation efficiency than the second component, overall a lower electrical power may be input to the module in the second operating mode.

The module may comprise a third radiation-emitting component, wherein the third radiation-emitting component emits radiation of a third wavelength differing from the first wavelength. The third radiation-emitting component may exhibit a third luminous flux. In this case, in the first operating mode the ratio of the first luminous flux, the second luminous flux and the third luminous flux may be set such that the module emits mixed radiation with a color rendering index of 80 to 97. In the second operating mode, the ratio of the first luminous flux, the second luminous flux and the third luminous flux may be set such that the module emits mixed radiation with a color rendering index of 55 to 70.

In the first operating mode, the ratio of the luminous fluxes of the three components may be set such that a variable cool white or warm white color location of 2100 K to 6500 K is achieved. In the second operating mode, the proportion of luminous flux of the first red component may be reduced such that the electrical power input may be optimized.

The third wavelength may be in the blue spectral range. In this case, the first component emits red radiation and the second component greenish-white radiation.

The third wavelength may be in the wavelength range of the second wavelength. The third component and the second component accordingly emit radiation in the same wavelength range, preferably in the greenish-white spectral range. The second and third components preferably emit greenish-white radiation converted to different degrees.

In the second operating mode, the greenish-white components may advantageously be dimmed such that a desired irradiance is generated in the respective intended use.

The first, second and/or third radiation-emitting component may be an LED (light-emitting diode). In this case, the components may each comprise an active layer that generates electromagnetic radiation. The active layer may then comprise a pn-junction, a double heterostructure, a single quantum well structure (SQW) or a multi quantum well structure (MQW) for radiation generation. The term quantum well structure does not here have any meaning with regard to the dimensionality of the quantization. It thus encompasses inter alia quantum troughs, quantum wires and quantum dots and any combination of these structures.

The components, in particular the active layer, each contain in each case at least one III/V semiconductor material, for instance a material from the material systems InₓGa_{y}Al_{1-x-y}P, InₓGa_{y}Al_{1-x-y}N or InₓGa_{y}Al_{1-x-y}As, in each case with 0≦x, y≦1 and x+y≦1.

The module may comprise a plurality of first radiation-emitting components, a plurality of second radiation-emitting components and/or a plurality of third radiation-emitting components. The number of respective components may be adapted to the respective application. There is preferably at least one more second component than first components. In this case, the first components emit or yield less light than the second components. The first components are, for example, red LEDs, the second components greenish-white LEDs and the third components blue or greenish-white LEDs.

The light-emitting diode module may be intended for street lighting, tunnel lighting, indoor car park lighting and/or warehouse lighting.

The first operating mode of the light-emitting diode module is intended for peak hour operation and the second operating mode for operation outside peak hours. Outside peak hours the quality required of the module is lower than during peak hours. In particular, outside peak hours there is less traffic on the roads, or the like. It is therefore sufficient for the module to operate with a lower color rendering index and thus lower quality to achieve the intended module application, for example, simply to help people find their way. The module may thus be operated in the second operating mode outside peak hours, the module being operable with a reduced electrical power input during these periods.

If the module is used for lighting indoor car parks, the second operating mode may provide “emergency lighting,” for example, if the car park is locked at certain specific times and is thus inaccessible, the car park only needs emergency lighting to allow people to find their way. In this case, the module is operated in the second mode, the brightness of the components operated in this mode additionally being dimmed by reducing the electrical power input.

Such “emergency lighting” may also be used for other applications such as, for example, in a module located in a tunnel.

Depending on the respective application and use intended for the module, the electrical power input to the module may be adapted optimally and economically sensibly.

In a method of producing a light-emitting diode module having at least one first radiation-emitting component and one second radiation-emitting component and having a first operating mode and a second operating mode, the following method steps are used:
providing a carrier,
arranging the first radiation-emitting component and the second radiation-emitting component on the carrier, wherein
the first radiation-emitting component emits radiation of a first wavelength and exhibits a first luminous flux,
the second radiation-emitting component emits radiation of a second wavelength differing from the first wavelength and exhibits a second luminous flux,
in the first operating mode, at least the ratio of the first luminous flux to the second luminous flux is set such that the module emits mixed radiation with a color rendering index of 80 to 97,
in the second operating mode, at least the ratio of the first luminous flux to the second luminous flux is set such that the module emits mixed radiation with a color rendering index of 55 to 70.

Variations in the method arise in a manner similar to the variations of the component and vice versa.

A third radiation-emitting component is arranged on the carrier, which third component emits radiation of a third wavelength differing from the first wavelength and exhibits a third luminous flux. In this case, in the first operating mode the ratio of the first luminous flux, the second luminous flux and the third luminous flux is set such that the module emits mixed radiation with a color rendering index of 80 to 97. In the second operating mode, the ratio of the first luminous flux, the second luminous flux and the third luminous flux is set such that the module emits mixed radiation with a color rendering index of 55 to 70.

The perceived color and the color temperature of the mixed radiation in the first and second operating modes differs according to the intended use. In particular, the module emits a cool white or warm white color shade in the first operating mode, while in the second operating mode the module preferably emits mixed radiation in the greenish-whitish color location.

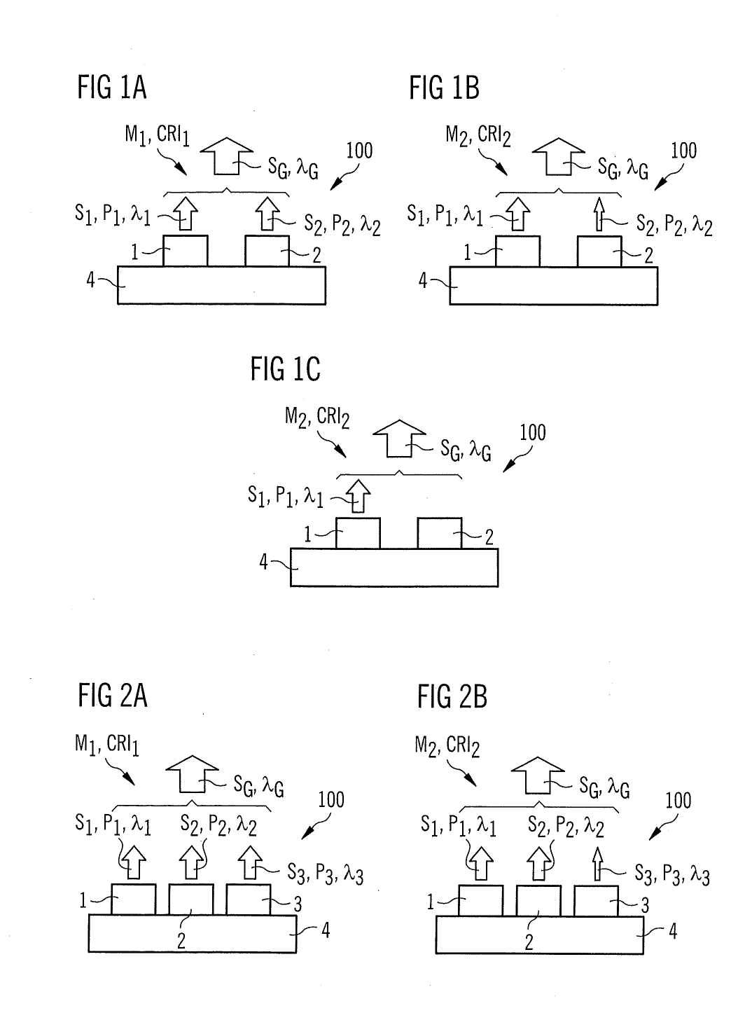

Further features, advantages, further developments and convenient aspects of the module and of the method for the production thereof are revealed by the examples explained below in conjunction with FIGS. 1 to 5.

Identical or equivalently acting components are denoted with identical reference numerals. The components illustrated and the size ratios of the components to one another should not be regarded as to scale.

FIG. 1A shows a light-emitting diode module 100 comprising a carrier 4, a first radiation-emitting component 1 arranged thereon and a second radiation-emitting component 2 arranged on the carrier 4. The first radiation-emitting component 1 emits radiation of a first wavelength λ₁ and exhibits a first luminous flux P₁. The second radiation-emitting component 2 emits radiation of a second wavelength λ₂ differing from the first wavelength λ₁ and exhibits a second luminous flux P₂.

The radiation-emitting components 1, 2 each comprise an active layer that generates electromagnetic radiation when in operation. The radiation-emitting components 1, 2 are semiconductor components, preferably LEDs, preferably thin-film LEDs.

The first wavelength λ₁ is, for example, in the red spectral range and the second wavelength λ₂ is in the greenish-white spectral range.

The radiation-emitting components 1, 2 each comprise a radiation exit side remote from the carrier 4. The radiation emitted by the components preferably exits for the most part from the radiation exit side. Components 1, 2 are surface-emitting components, for example.

The light-emitting diode module 100 emits mixed radiation S_{G} when in operation, in which radiation emitted by the first component 1 and radiation emitted by the second component 2 are superimposed. The mixed radiation S_{G} emitted by the light-emitting diode module 100 is preferably white radiation.

FIGS. 1A to 1C each show an operational light-emitting diode module 100 in different operating modes. The light-emitting diode module 100 thus comprises a first operating mode M₁ and a second operating mode M₂ in which the light-emitting diode module 100 may be operated. Switching from the first operating mode to the second operating mode, or vice versa, is preferably possible.

The operating modes differ in particular in the ratio of first luminous flux P₁ to second luminous flux P₂. In the first operating mode M₁ as shown, for example, in FIG. 1, the ratio of first luminous flux P₁ to second luminous flux P₂ is set such that the module 100 emits mixed radiation S_{G} with a color rendering index CRI₁ of 80 to 97. In the first operating mode M₁ the module thus emits radiation of high quality. For example, the light-emitting diode module 100 of the example of FIG. 1A emits mixed radiation S_{G} in the cool or warm white spectral range.

If the light-emitting diode module is operated in the first operating mode M₁, as illustrated in FIG. 1A, the radiation emission and color rendering index generated are of high quality, the color temperature lying in the cool white or warm white spectral range. The electrical power L₁, L₂ input to the components 1, 2 is in this case preferably set such that the highest possible quality can be achieved for the emitted mixed radiation. The first operating mode of the module may also be designated “high electrical mode.”

The module 100 exhibits a second operating mode M₂, which may also be designated “reduced electrical mode.” Depending on the desired use, the module may be or have been set to one of the modes. A module operated in the second operating mode is shown, for example, in FIGS. 1B and 1C.

Unlike in the module operated in the first operating mode M₁, the electrical power L₁ input to the first radiation-emitting component 1 and thus the radiation emission and luminous flux of the first component 1 are reduced in the second operating mode M₂. This results in mixed radiation S_{G} of the module with a lower color rendering index CRI₂ than in the first operating mode. In the second operating mode, the color rendering index is, for example, 55 to 70, while the color rendering index in the first mode is 80 to 97.

The color temperature of the mixed radiation S_{G} also changes as compared with the first operating mode M₁. In the first operating mode M₁, the mixed radiation is in the cool or warm white spectral range. In contrast, the mixed radiation in the second operating mode M₂ is in the greenish-white spectral range. In the second operating mode the module 100 thus emits mixed radiation of a lower quality than in the first operating mode M₁, in particular with a lower color rendering index and a different color temperature, the second operating mode M₂ advantageously being distinguished by reduced electrical power input to the module. The module may thus be or have been set to an appropriate mode for the intended use. The module is accordingly definitely not only operable in the first operating mode M₁ which, while distinguished by a high color quality, also has higher electricity consumption than the second operating mode M₂.

In the second operating mode M₂, it is possible as shown in FIG. 1B, for the first component 1 and the second component 2 to be electrically driven. In this case, the electrical power input to the first component 1 and the luminous flux thereof are reduced compared with the first operating mode M₁. Alternatively, the light-emitting diode module 100, as shown in FIG. 1C, may be operated such that in the second operating mode M₂ only the second electrical component 2 is electrically driven.

Since the first component 1, i.e., the red-emitting LED, exhibits poorer radiant power, in the second operating mode M₂ the radiant power of the module may be increased overall. This results in an increase in efficiency of 20% to 30%, for example.

In FIGS. 1A to 1C the radiation emitted by the individual components 1, 2 and the module 100 is shown by arrows.

FIGS. 2A, 2B each show a light-emitting diode module 100 comprising three radiation-emitting components 1, 2, 3 arranged side by side on the carrier 4.

The example of FIG. 2A differs from the example of FIG. 1A substantially through this third component 3. The example of FIG. 2A is in the first operating mode M₁. The example of FIG. 2B differs from the example of FIG. 1B substantially solely through the third component 3, wherein this light-emitting diode module 100 is in the second operating mode M₂.

The third component 3 emits radiation, when in operation, of a third wavelength λ₃ different from the first wavelength λ₁. When in operation, the third component 3 exhibits a third luminous flux P₃. The third wavelength λ₃ is preferably in the blue wavelength range. Alternatively, the third wavelength λ₃ may be in the wavelength range of the second wavelength λ₂, i.e., in the greenish-white wavelength range.

In the first operating mode, as shown in FIG. 2A, the ratio of the first luminous flux P₁, the second luminous flux P₂ and the third luminous flux P₃ is set such that the module 100 emits mixed radiation S_{G} with a color rendering index CRI₁ of 80 to 97. A module operated by such operation thus exhibits a high color quality for the emitted mixed radiation.

In the second operating mode, on the other hand, the ratio of the first luminous flux P₁, the second luminous flux P₂ and the third luminous flux P₃ is set such that the module 100 emits mixed radiation S_{G} with a color rendering index CRI₂ of 55 to 70, as shown in FIG. 2B. The color quality of the radiation is thus reduced relative to the first operating mode, wherein the electrical power input is thereby advantageously reduced. The second operating mode thus constitutes a reduced electrical mode with economically appropriate electrical power input.

Otherwise, the example of FIG. 2A substantially corresponds to the example of FIG. 1A and the example of FIG. 2B corresponds substantially to the example of FIG. 1B.

FIGS. 3A and 3B each show a further cross-section of a light-emitting diode module. The example of FIG. 3A differs from the example of FIG. 2A in that the module comprises a plurality of first radiation-emitting components 1, a plurality of second radiation-emitting components 2 and a plurality of third radiation-emitting components 3. In this case, the module 100 emits mixed radiation S_{G} consisting of the emitted mixed radiations of the first components 1, the second components 2 and the third components 3. The module 100 of the example of FIG. 3A operates in the first operating mode M₁, i.e., with high color quality and high electrical consumption.

The example of FIG. 3B shows a module of the example of FIG. 3A in the second operating mode M₂. The module thus emits mixed radiation S_{G} of a lower color quality, a different color temperature and a lower electrical consumption.

In the second operating mode, the proportion of luminous flux of the first component is reduced or deactivated. Optionally, the luminous flux of the second and/or third component may additionally be reduced. In addition, the second and/or third component may additionally be dimmed to achieve the desired irradiance for an intended use.

Otherwise, the example of FIG. 3A substantially corresponds to the example of FIG. 2A and the example of FIG. 3B corresponds substantially to the example of FIG. 2B.

The light-emitting diode modules shown in FIGS. 1 to 3 are particularly suitable for use as street lighting, tunnel lighting, car park lighting or warehouse lighting. In this case, the light-emitting diode modules are preferably operated in the first operating mode during peak hours, while the modules may be operated in the second operating mode outside peak hours. It is advisable specifically during peak hours for such modules to be operated with high color quality. Outside peak hours, i.e., during quiet periods, on the other hand, a lower color quality is sufficient for the radiation emitted by the modules to obtain the intended technical effect namely, for example, to serve as street lighting.

Modules used in this way are thus not operated for the entire day at high color quality and high electrical consumption, but rather may also exhibit a second operating mode distinguished by electrically appropriate consumption.

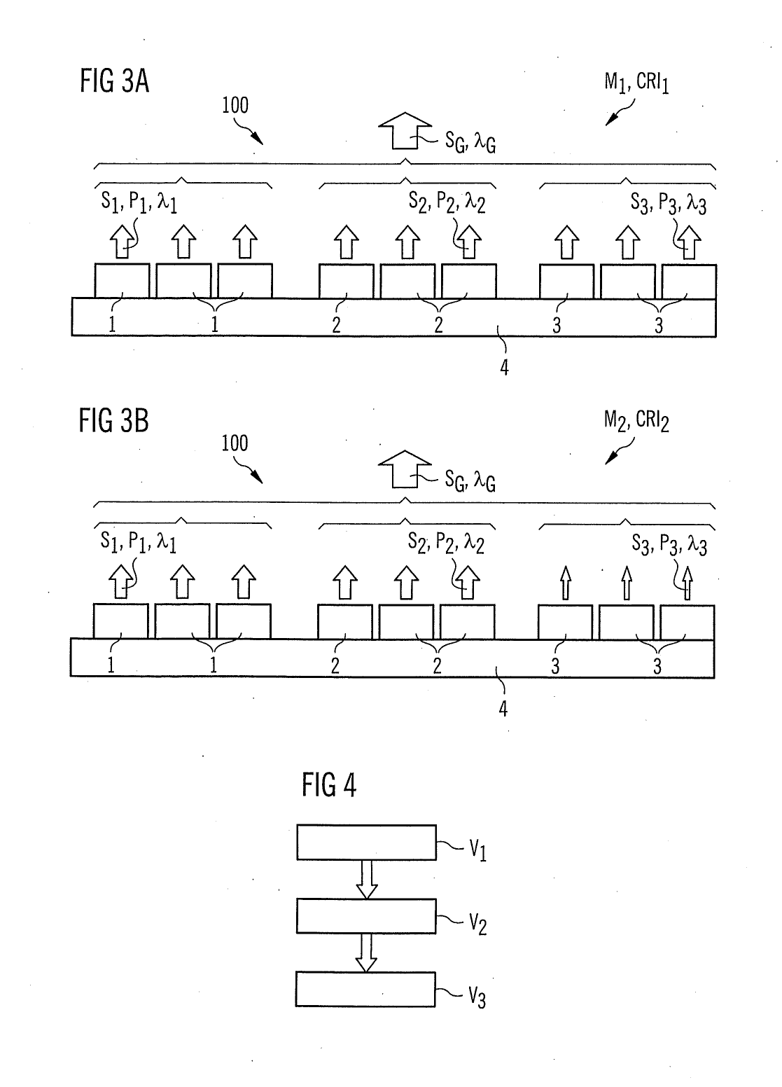

FIG. 4 shows a flow chart for the production of a light-emitting diode module 100. In method step V1, a carrier is provided on which at least one first radiation-emitting component 1 and one second radiation-emitting component 2 are arranged in method step V2.

To establish the operating modes of the light-emitting diode module, in method step V3 the first operating mode and the second operating mode are set. In the first operating mode, the ratio of the first luminous flux to the second luminous flux is set such that the module emits mixed radiation with a color rendering index of 80 to 97. In the second operating mode, the ratio of the first luminous flux to the second luminous flux is set such that the module emits mixed radiation with a color rendering index of 55 to 70. To this end, in the second mode the luminous flux of the first component is reduced or adjusted to zero.

A module produced in this way thus exhibits two operating modes which differ in color quality, color temperature and electrical consumption. An operating mode of the module may thus be selected depending on the intended and desired application.

A production method described in conjunction with FIG. 4 is suitable in particular for the production of a light-emitting diode module according to one of the examples of FIG. 1, 2 or 3.

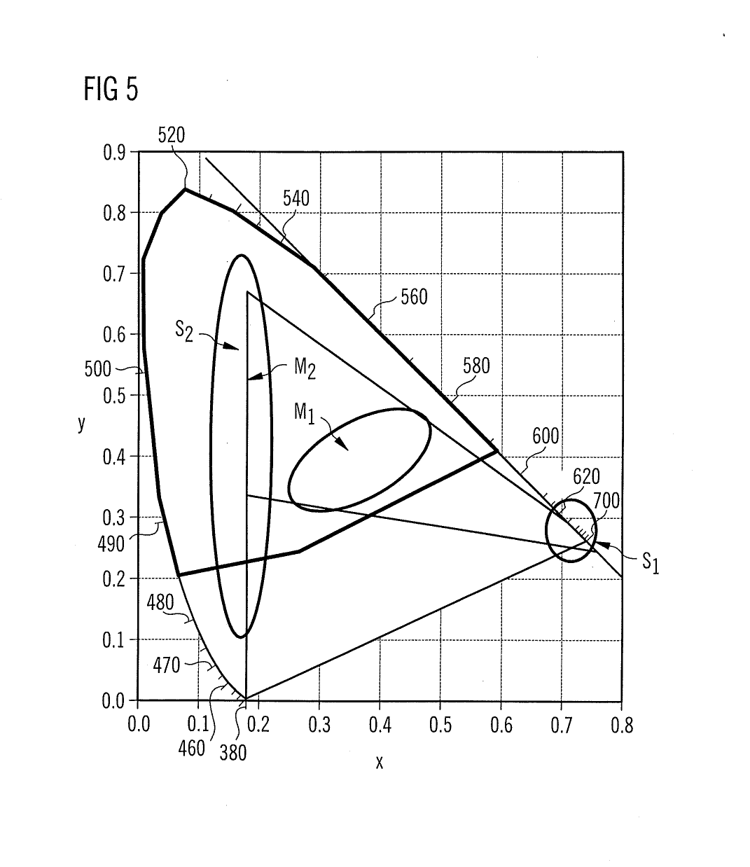

FIG. 5 is a CIE standard chromaticity diagram showing the three-dimensional color space perceived by the observer. The horseshoe-shaped area of possible colors is plotted on a system of coordinates from which the X and Y fractions of the CIE standardized theoretical primary colors X (red), Y (green), and Z (blue) of any desired color may be read off directly. The standard chromaticity diagram shows the radiation S₂ emitted by the first component. The wavelength spectrum emitted is in the red spectral range. Such LEDs exhibit low light yield.

In addition, the radiation S₂ emitted by the second component is shown, the wavelength of which is in the greenish-white spectral range. Alternatively, monochromatic, yellow or green LEDs may also be used as second components.

The mixed radiation emitted by the module in the first operating mode is shown in the standard chromaticity diagram by reference numeral M1. Such a spectrum exhibits good efficiency with very good color rendering in a color temperature range in the cool white or warm white spectral range. In this operating mode M1, both the first component and the second component are electrically driven. Thus the red LED and the greenish-white LED are driven when the module is operated in the first mode.

The second operating mode M₂ is likewise shown in the standard chromaticity diagram. This spectrum emitted in the operating mode has higher efficiency with lower color rendering. In this mode, for example, only the second component, i.e., the greenish-white LED, is operated or electrically driven.

The module may be operated in both modes such that the correct mode of the module may be selected depending on the intended use.

Our modules and methods are not limited to the examples as a result of the description made with reference thereto, but instead this disclosure encompasses any novel feature and any combination of features, including in particular any combination of features in the appended claims, even if the features or combination is not itself explicitly indicated in the claims or examples.

1-14. (canceled)

15. A light-emitting diode module comprising at least one first radiation-emitting component and one second radiation-emitting component and having, a first operating mode and a second operating mode, wherein
the first radiation-emitting component emits radiation of a first wavelength and exhibits a first luminous flux,
the second radiation-emitting component emits radiation of a second wavelength different from the first wavelength and exhibits a second luminous flux,
at least a ratio of the first luminous flux to the second luminous flux in the first operating mode is set such that the module emits mixed radiation with a color rendering index of 80 to 97,
at least a ratio of the first luminous flux to the second luminous flux in the second operating mode is set such that the module emits mixed radiation with a color rendering index of 55 to 70,
the first wavelength is in a red spectral range and the second wavelength is in a greenish-white spectral range,
the lighting module is adapted for use in street lighting, tunnel lighting, indoor car park lighting and/or warehouse lighting, and
the lighting module comprises two operating modes.

16. The light-emitting diode module according to claim 15, wherein the wavelength of the mixed radiation in the first operating mode is in a cool or warm white spectral range and the wavelength of the mixed radiation in the second operating mode is in a greenish-white spectral range.

17. The light-emitting diode module according to claim 15, wherein, in the second operating mode, electrical power input to the first radiation-emitting component and/or the radiation emission thereof is lower than electrical power input to the second radiation-emitting component and/or the radiation emission thereof.

18. The light-emitting diode module according to claim 15, further comprising a third radiation-emitting component that emits radiation of a third wavelength different from the first wavelength and exhibits a third luminous flux.

19. The light-emitting diode module according to claim 18, wherein the third wavelength is in a blue spectral range.

20. The light-emitting diode module according to claim 18, wherein the third wavelength is in a wavelength range of the second wavelength.

21. The light-emitting diode module according to claim 15, wherein the first, second and/or third radiation-emitting component is an LED.

22. The light-emitting diode module according to claim 15, comprising a plurality of first radiation-emitting components, a plurality of second radiation-emitting components and/or a plurality of third radiation-emitting components.

23. The light-emitting diode module according to claim 15, which, in the first operating mode, operates during peak hours and, in the second operating mode, operates outside peak hours.

24. A method of producing a light-emitting diode having at least one first radiation-emitting component and one second radiation-emitting component having a first operating mode and a second operating mode comprising:
providing a carrier,
arranging the first radiation-emitting component and the second radiation-emitting component on the carrier, wherein
the first radiation-emitting component emits radiation of a first wavelength and exhibits a first luminous flux,
the second radiation-emitting component emits radiation of a second wavelength different from the first wavelength and exhibits a second luminous flux,
at least a ratio of the first luminous flux to the second luminous flux in the first operating mode is set such that the module emits mixed radiation with a color rendering index of 80 to 97,
at least a ratio of the first luminous flux to the second luminous flux in the second operating mode is set such that the module emits mixed radiation with a color rendering index of 55 to 70,
the first wavelength is in a red spectral range and the second wavelength is in a greenish-white spectral range,
the lighting module is adapted for street lighting, tunnel lighting, indoor car park lighting and/or warehouse lighting, and
the lighting module comprises two operating modes.

25. The method according to claim 24, further comprising arranging a third radiation-emitting component that emits radiation of a third wavelength different from the first wavelength and exhibits a third luminous flux on the carrier.

26. A light-emitting diode module comprising at least one first radiation-emitting component and one second radiation-emitting component and having a first operating mode and a second operating mode,
wherein
the first radiation-emitting component emits radiation of a first wavelength and exhibits a first luminous flux,
the second radiation-emitting component emits radiation of a second wavelength different from the first wavelength and exhibits a second luminous flux,
at least a ratio of the first luminous flux to the second luminous flux in the first operating mode is set such that the module emits mixed radiation with a color rendering index of 80 to 97, and
at least a ratio of the first luminous flux to the second luminous flux in the second operating mode is set such that the module emits mixed radiation with a color rendering index of 55 to 70.
